(19) United States
(12) Patent Application Publication
(10) Pub. No.: US 2026/0353770 A1
(43) Pub. Date: Nov. 5, 2026

(54) SEMICONDUCTOR DEVICE, METHOD OF MANUFACTURING SEMICONDUCTOR DEVICE, SEMICONDUCTOR MODULE, AND ELECTRONIC APPARATUS

(71) Applicant: Sony Semiconductor Solutions Corporation, Kanagawa (JP)

(72) Inventor: Shinya Morita, Tokyo (JP)

(21) Appl. No.: 19/102,680

(22) PCT Filed: Aug. 8, 2023
(86) PCT No.: PCT/JP2023/028883

§ 371 Date: Feb. 10, 2025

(30) Foreign Application Priority Data
Sep. 20, 2022 (JP) 2022-149237

(51) Int. Cl. H10D 84/80; H10D 8/01; H10D 8/60; H10D 30/01; H10D 30/47; H10D 62/60; H10D 62/85; H10D 64/27; H10D 64/64; H10D 84/01

(52) U.S. Cl. CPC H10D 84/811; H10D 8/051; H10D 8/60; H10D 30/015; H10D 30/475; H10D 62/60; H10D 62/8503; H10D 64/518; H10D 64/64; H10D 84/0109

(57) ABSTRACT

A semiconductor device includes: a first compound semiconductor; a first electrode disposed on the first compound semiconductor, the first electrode being coupled to the first compound semiconductor by Schottky junction; a second compound semiconductor disposed on the first compound semiconductor at a distance from the first electrode, the second compound semiconductor having a higher impurity density than the first compound semiconductor; and a second electrode disposed on the second compound semiconductor, the second electrode including the same electrically conductive material as the first electrode and being coupled to the second compound semiconductor by ohmic junction.

### TECHNICAL FIELD

The present disclosure relates to a semiconductor device, a method of manufacturing a semiconductor device, a semiconductor module, and electronic apparatus.

### BACKGROUND ART

Patent Literature 1 discloses a semiconductor element as a diode for electric power. The semiconductor element includes a semiconductor layer, an anode section, and a cathode section.

The semiconductor layer is formed using a wide-gap material and formed with electrons as majority carriers. The anode section is formed by junction formation on a main surface of the semiconductor layer and acts as an anode of the semiconductor element. The cathode section is formed by junction formation on another region of the main surface of the semiconductor layer and acts as a cathode of the semiconductor element.

The semiconductor element such configured allows good characteristics to be obtained as a diode for electric power.

### CITATION LIST

### Patent Literature

Patent Literature 1: Japanese Unexamined Patent Application Publication No. 2007-249919

### SUMMARY OF THE INVENTION

In the semiconductor element described above, the anode section and the cathode section are formed of respective two different types of electrode materials. In view of this, a semiconductor device that uses a compound semiconductor and that includes a diode formed of a single type of electrode material, a method of manufacturing the semiconductor device, a semiconductor module implemented with the semiconductor device, and an electronic apparatus are desired.

A semiconductor device according to a first aspect of the present disclosure includes: a first compound semiconductor; a first electrode disposed on the first compound semiconductor, the first electrode being coupled to the first compound semiconductor by Schottky junction; a second compound semiconductor disposed on the first compound semiconductor at a distance from the first electrode, the second compound semiconductor having a higher impurity density than the first compound semiconductor; and a second electrode disposed on the second compound semiconductor, the second electrode including the same electrically conductive material as the first electrode and being coupled to the second compound semiconductor by ohmic junction.

A method of manufacturing a semiconductor device according to a second aspect of the present disclosure includes: forming, on a portion of a first compound semiconductor, a second compound semiconductor having a higher impurity density than the first compound semiconductor; forming a first electrode on the first compound semiconductor at a distance from the second compound semiconductor, the first electrode forming Schottky junction; and formning, in a same process as the forming the first electrode, a second electrode on the second compound semiconductor, the second electrode forming ohmic junction.

A semiconductor module according to a third aspect of the present disclosure includes a semiconductor device. The semiconductor device includes: a first compound semiconductor; a first electrode disposed on the first compound semiconductor, the first electrode being coupled to the first compound semiconductor by Schottky junction; a second compound semiconductor disposed on the first compound semiconductor at a distance from the first electrode, the second compound semiconductor having a higher impurity density than the first compound semiconductor; and a second electrode disposed on the second compound semiconductor, the second electrode including the same electrically conductive material as the first electrode and being coupled to the second compound semiconductor by ohmic junction.

An electronic apparatus according to the third aspect of the present disclosure includes a semiconductor device. The semiconductor device includes: a first compound semiconductor; a first electrode disposed on the first compound semiconductor, the first electrode being coupled to the first compound semiconductor by Schottky junction; a second compound semiconductor disposed on the first compound semiconductor at a distance from the first electrode, the second compound semiconductor having a higher impurity density than the first compound semiconductor; and a second electrode disposed on the second compound semiconductor, the second electrode including the same electrically conductive material as the first electrode and being coupled to the second compound semiconductor by ohmic junction.

### BRIEF DESCRIPTION OF THE DRAWINGS

FIG. 1 is a circuit diagram including an electro static discharge protection circuit and an inner circuit that are mounted in a semiconductor device according to a first embodiment of the present disclosure.

FIG. 2 is a longitudinal cross-sectional view of semiconductor elements included in the electro static discharge protection circuit and the inner circuit illustrated in FIG. 1.

FIG. 3 is an enlarged longitudinal cross-sectional view of semiconductor elements included in the electro static discharge protection circuit illustrated in FIG. 2.

FIG. 4 is a current-voltage characteristic diagram of the electro static discharge protection circuit illustrated in FIG. 2.

FIG. 5 is a current-voltage characteristic diagram of the electro static discharge protection circuit illustrated in FIG. 2.

FIG. 6 is, for process-by-process illustration of a method of manufacturing the semiconductor device according to the first embodiment, a first process cross-sectional view corresponding to FIG. 2.

FIG. 7 is a second process cross-sectional view.

FIG. 8 is a third process cross-sectional view.

FIG. 9 is a fourth process cross-sectional view.

FIG. 10 is a fifth process cross-sectional view.

FIG. 11 is a circuit diagram, corresponding to FIG. 1, including an electro static discharge protection circuit and an inner circuit that are mounted in a semiconductor device according to a second embodiment of the present disclosure.

FIG. 12 is a longitudinal cross-sectional view, corresponding to FIG. 2, of semiconductor elements included in the electro static discharge protection circuit and the inner circuit illustrated in FIG. 11.

FIG. 13 is a circuit diagram including an electro static discharge protection circuit mounted in a semiconductor device according to a third embodiment of the present disclosure.

FIG. 14 is a longitudinal cross-sectional view of semiconductor elements included in the electro static discharge protection circuit illustrated in FIG. 13.

FIG. 15 is a circuit diagram, corresponding to FIG. 13, of an electro static discharge protection circuit mounted in a semiconductor device according to a fourth embodiment of the present disclosure.

FIG. 16 is a longitudinal cross-sectional view, corresponding to FIG. 14, of semiconductor elements included in the electro static discharge protection circuit illustrated in FIG. 15.

FIG. 17 is a perspective view of a semiconductor module according to a fifth embodiment of the present disclosure.

FIG. 18 is a block configuration diagram of electronic apparatus according to a sixth embodiment of the present disclosure.

### MODES FOR CARRYING OUT THE INVENTION

Hereinafter, embodiments of the present disclosure will be described in detail with reference to the drawings. Note that the description will be given in the following order.
1. First Embodiment

A first embodiment is a first example where the present technique is applied to a semiconductor device including an electro static discharge protection circuit and an inner circuit that are mounted therein. Here, circuit configurations, cross-sectional configurations, and manufacturing methods of the electro static discharge protection circuit and inner circuit are described. In particular, operating characteristics of the electro static discharge protection circuit are also described.
2. Second Embodiment

A second embodiment is a second example where a change is made in the configuration of the electro static discharge protection circuit in the semiconductor device according to the first embodiment.
3. Third Embodiment

A third embodiment is a third example where a change is made in the configuration of the electro static discharge protection circuit in the semiconductor device according to the first embodiment.
4. Fourth Embodiment

A fourth embodiment is a fourth example where a change is made in the configuration of the electro static discharge protection circuit in the semiconductor device according to the first embodiment.
5. Fifth Embodiment

A fifth embodiment is a fifth example that describes a semiconductor module implemented with the semiconductor device according to any one of the first to fourth embodiments.
6. Sixth Embodiment

A sixth embodiment is a sixth example that describes electronic apparatus implemented with the semiconductor device according to any one of the first to fourth embodiments.
7. Other Embodiments

### 1. First Embodiment

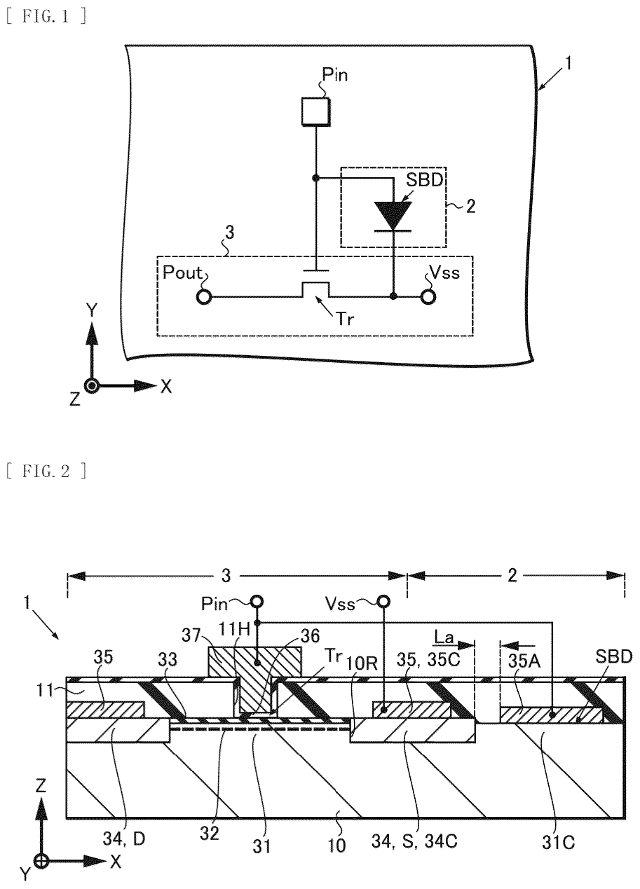

The semiconductor device 1 according to the first embodiment of the present disclosure will be described with reference to FIGS. 1 to 10.

Here, an arrow X direction indicated as appropriate in the drawings represents one plane direction of the semiconductor device 1 conveniently placed on a plane. An arrow Y direction represents another plane direction orthogonal to the arrow X direction. In addition, an arrow Z direction represents au up direction orthogonal to the arrow X direction and arrow Y direction. In other words, the arrow X direction, arrow Y direction, and arrow Z direction respectively correspond to an X axis direction, Y axis direction, and Z axis direction in a three-dimensional coordinate system exactly.

Note that these directions are illustrated to help understanding of the description, not to limit directions in the present technique.

### Configuration of Semiconductor Device 1

### (1) Circuit Configurations of Electro Static Discharge Protection Circuit 2 and Immer Circuit 3

FIG. 1 illustrates an example of a circuit configuration including an electro static discharge (ESD) protection circuit 2 and an inner circuit 3 that are mounted in the semiconductor device 1 according to the first embodiment.

As illustrated in FIG. 1, the semiconductor device 1 includes the electro static discharge protection circuit 2 and the inner circuit 3.

In the first embodiment, the inner circuit 3 includes, as a main component, a field effect transistor Tr included in, for example, a power device, a high-frequency device, or the like. As the field effect transistor Tr, for example, a high electron mobility transistor (HEMT) is used. Here, the field effect transistor Tr is of n-channel conductive type.

The field effect transistor Tr includes a gate electrode and a pair of main electrodes.

The gate electrode of the field effect transistor Tr serving as an input stage of the inner circuit 3 is coupled to an input terminal Pin. The input terminal Pin receives a signal from outside of the semiconductor device 1.

One of the main electrodes of the field effect transistor Tr is used as a source region (source electrode), for example. The one of the main electrodes is coupled to a power source terminal Vss. The power source terminal Vss supplies, for example a fixed electric potential, specifically a ground voltage 0V of the circuit. Another one of the main electrodes is used as a drain region (drain electrode), for example. The other one of the main electrodes is used as an output terminal Pout and coupled to a next-stage circuit or a next-stage element.

The electro static discharge protection circuit 2 includes, here, a Schottky barrier diode SBD.

An anode region (or anode electrode) of the Schottky barrier diode SBD is electrically connected in parallel between the input terminal Pin and the gate electrode of the field effect transistor Tr. Meanwhile, a cathode region (or cathode electrode) of the Schottky barrier diode SBD is electrically connected in parallel between the one of the main electrodes of the field effect transistor Tr and the power source terminal Vss.

### (2) Specific Device Configuration of Field Effect Transistor Tr

FIG. 2 illustrates an example of a longitudinal cross-sectional configuration of the field effect transistor Tr included in the inner circuit 3 and the Schottky barrier diode SBD included in the electro static discharge protection circuit 2.

As illustrated in FIG. 2, the semiconductor device 1 is provided with a substrate 10 as a base. Here, in the first embodiment, the substrate 10 is formed of gallium nitride (GaN) being a semiconductor material of group III-V compounds as a first compound semiconductor. The first compound semiconductor is formed as i-GaN, a so-called intrinsic semiconductor. The first compound semiconductor has an impurity density of 1×10¹⁷ [atoms/cm³] or less, for example.

Note that the substrate 10 may be formed by stacking or bonding a GaN layer as the first compound semiconductor on or to a silicon (Si) substrate, a silicon carbide (SIC) substrate, or a diamond substrate.

Here, the first compound semiconductor corresponds to a “first compound semiconductor” according to the present technique.

The field effect transistor Tr includes, as main components, a channel layer 31, a barrier layer 33, a gate insulating layer 36, a gate electrode 37, and a pair of main electrodes 34.

The channel layer 31 is provided in at least a main surface portion of the substrate 10. In other words, the channel layer 31 is, here, formed of GaN.

In the channel layer 31, in the vicinity of the barrier layer 33, carriers are accumulated and two-dimensional electron gas (2DEG) 32 that functions as a channel region of the carriers is generated.

The barrier layer 33 is disposed on the channel layer 31. The barrier layer 33 is formed of a compound semiconductor material that carriers are accumulated in the channel layer 31 by polarization with the channel layer 31. The barrier layer 33 is formed of Al_{1-x-y}GaₓIn_{y}N (0≤x<1, 0≤y<1), for example.

The gate insulating layer 36 is disposed on the barrier layer 33 on a side opposite to the channel layer 31. Here, the gate insulating layer 36 is formed through an opening 11H penetrating an interlayer insulator 11 in the width direction. For the gate insulating layer 36, one or more insulating materials selected from, for example, aluminum oxide (Al₂O₃), hafnium oxide (HIO₂), silicon oxide (SiO₂), and silicon nitride (SiN) are used.

The gate electrode 37 is, at least in the opening 11H, disposed on the gate insulating layer 36 on a side opposite to the barrier layer 33. The gate electrode 37 includes, here, a composite film obtained by stacking, for example, nickel (Ni) and gold (Au) successively in the arrow Z direction. In other words, the field effect transistor Tr is configured as a field effect transistor of gate insulating type.

The pair of main electrodes 34 is disposed at respective ones of both ends in a gate length direction of the gate electrode 37. The one of the main electrodes 34 is used as the source electrode(S), for example. The other one of the main electrodes 34 is used as the drain electrode (D), for example.

The pair of main electrodes 34 is each disposed on the main surface portion of the substrate 10. In the first embodiment, specifically, the main electrodes 34 are each disposed in a recess 10R obtained by digging down from a surface of the substrate 10 in the width direction of the substrate 10.

Each main electrode 34 is formed of GaN as a second compound semiconductor. The main electrode 34 has an impurity density higher than that of the substrate 10. In other words, the second compound semiconductor included in the main electrode 34 has an impurity density higher than an impurity density of the first compound semiconductor included in the substrate 10.

In addition, the main electrode 34 is formed, in the recess 10R provided in the substrate 10, by re-growing GaN. For the growth of GaN, an epitaxial growth method is used.

The main electrode 34 has an n-type impurity density of 1×10¹⁹ [atoms/cm³] or more, for example.

Here, the second compound semiconductor corresponds to a “second compound semiconductor” according to the present technique.

The pair of main electrodes 34 is each provided with an electrode 35 disposed. The electrode 35 is formed of an electrode material that forms ohmic junction or junction close to ohmic junction with respect to the main electrode 34. For the electrode 35, a composite film obtained by stacking, for example, titanium (Ti), molybdenum (Mo), aluminum (AI), nickel (Ni), and gold (Au) successively is used.

Here, the electrode 35 corresponds to a “third electrode” according to the present technique.

### (3) Specific Device Configuration of Schottky Barrier Diode SBD

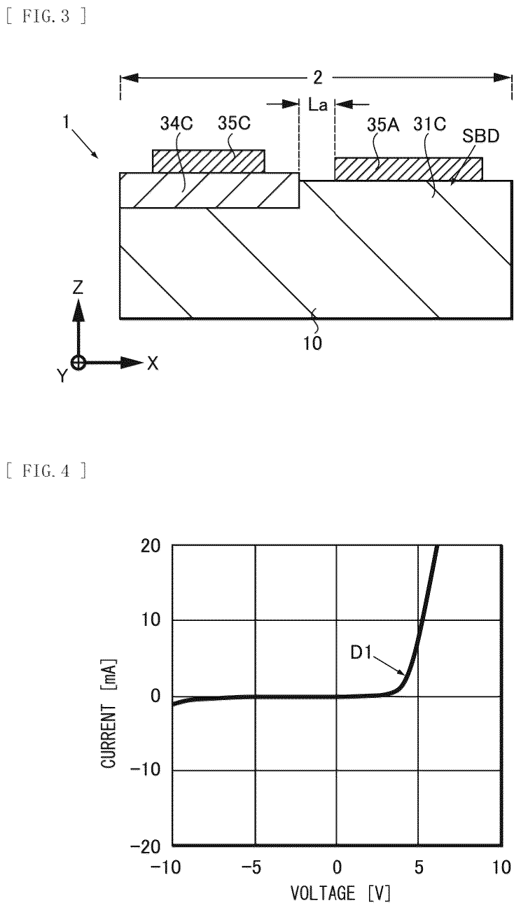

FIG. 3 illustrates an example of an enlarged longitudinal cross-sectional configuration of the Schottky barrier diode SBD included in the electro static discharge protection circuit 2.

As illustrated in FIGS. 2 and 3, the Schottky barrier diode SBD includes, as main components, an anode electrode 35A, a cathode region 31C, an extraction electrode 34C, and a cathode electrode 35C.

First, the cathode region 31C is provided in the main surface portion of the substrate 10. In other words, the cathode region 31C is formed of GaN as the first compound semiconductor.

In addition, the cathode region 31C includes an electrically conductive layer same as that of the channel layer 31 in the field effect transistor Tr and includes an electrically conductive material same as that of the channel layer 31.

The anode electrode 35A is disposed on the cathode region 31C. Specifically, the anode electrode 35A is in contact with a surface of the cathode region 31C and junction is formed therebetween. The anode electrode 35A is coupled to the surface of the cathode region 31C by Schottky junction. The anode electrode 35A is used also as an anode region. In other words, in the vicinity of junction between the anode electrode 35A and the cathode region 31C, the Schottky barrier diode SBD is substantially formed.

The anode electrode 35A includes an electrically conductive layer same as that of the electrode 35 in the field effect transistor Tr and includes an electrically conductive material same as that of the electrode 35.

Here, the anode electrode 35A corresponds to a “first electrode” according to the present technique.

The extraction electrode 34C is disposed on the substrate 10 at a distance from the anode electrode 35A. The extraction electrode 34C is formed of GaN as the second compound semiconductor disposed in the recess 10R provided in the substrate 10. The extraction electrode 34C includes an electrically conductive layer same as that of the main electrode 34 in the field effect transistor Tr and includes an electrically conductive material same as that of the main electrode 34. The extraction electrode 34C has an impurity density higher than that of the substrate 10. In the first embodiment, the extraction electrode 34C is formed integrally with the main electrode 34 in the field effect transistor Tr and is shared therebetween.

The extraction electrode 34C serves as a current path connecting the cathode region 31C and the cathode electrode 35C of the Schottky barrier diode SBD and forms ohmic junction with respect to the cathode electrode 35C.

The cathode electrode 35C is disposed on the extraction electrode 34C. Specifically, the cathode electrode 35C is in contact with a surface of the extraction electrode 34C and junction is formed therebetween. The cathode electrode 35C is coupled to the surface of the extraction electrode 34C by ohmic junction.

The cathode electrode 35C includes an electrically conductive layer same as that of the main electrode 34 in the field effect transistor Tr and the anode electrode 35A and includes an electrically conductive material same as that of the main electrode 34 and the anode electrode 35A. In the first embodiment, the cathode electrode 35C is formed integrally with the electrode 35 in the field effect transistor Tr and is shared therebetween. Here, the cathode electrode 35C corresponds to a “second electrode” according to the present technique.

### (4) Current-Voltage Characteristics of Schottky Barrier Diode SBD

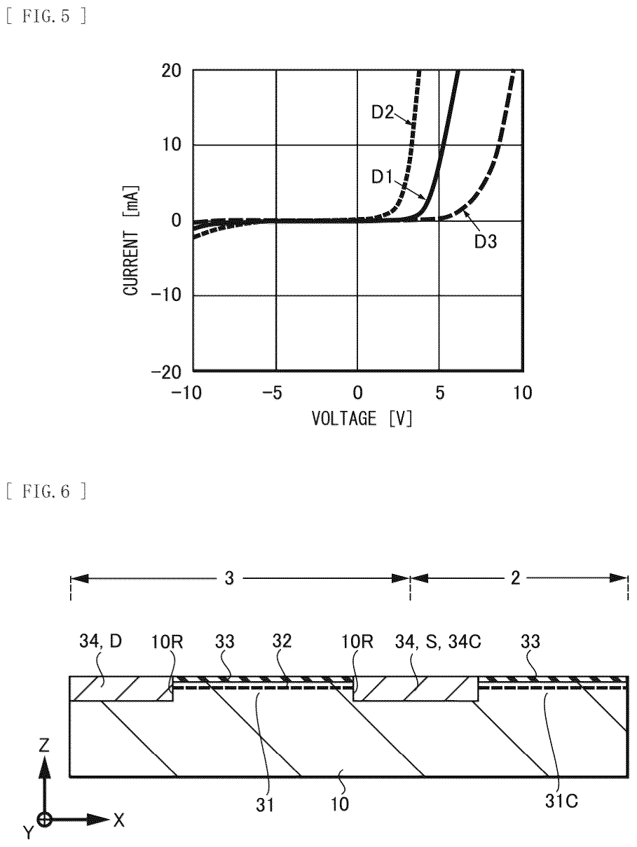

FIGS. 4 and 5 each illustrate an example of current-voltage characteristics of the Schottky barrier diode SBD.

In each of FIGS. 4 and 5, the horizontal axis indicates the driving voltage [V] of the Schottky barrier diode SBD. The vertical axis indicates the driving current [mA] flows through the Schottky barrier diode SBD.

As illustrated as data DI in FIG. 4, in the Schottky barrier diode SBD, the driving voltage rises and reaches a certain threshold voltage, and then the driving current flows. The amount of driving current increases as the driving voltage rises.

The driving current with respect to the driving voltage is controllable by adjusting a clearance La of the Schottky barrier diode SBD illustrated in FIG. 3 described above. The clearance La corresponds to a distance, along the surface of the substrate 10, between the anode-electrode-35A-side end of the extraction electrode 34C and the extraction-electrode-34-side end of the anode electrode 35A.

In the first embodiment, the clearance La is set in a range longer than 0 and 0.9 [μm] or shorter.

As illustrated as data D2 in FIG. 5, the shorter the clearance La the lower the threshold voltage. In a case where the clearance La is 0 or shorter, the extraction electrode 34C and the anode electrode 35A are in contact with each other, providing characteristics close to ohmic junction. In other words, such a case does not generate the Schottky barrier diode SBD, and thus the clearance La is required to be longer than 0. Meanwhile, as illustrated as data D3 in FIG. 5, the longer the clearance La the higher the threshold voltage. The operation voltage of the Schottky barrier diode SBD is set to be equal to or lower than a withstand voltage of the inner circuit 3. For example, in a case where the clearance La is longer than 1 [μm], the operation voltage is approximately 40 [V] or higher. In a case where the semiconductor device 1 is used, for example, for a mobile terminal, the operation voltage is set not to be higher than 40 [V]. Thus, the clearance La is adjusted to 0.9 [μm] or shorter. This enables both the electro static discharge protection performance and the device performance to be made compatible in the semiconductor device 1.

### Method of Manufacturing Semiconductor Device 1

Next, a method of manufacturing the semiconductor device 1 described above will be described. FIGS. 6 to 10 each illustrate an example of a cross section in a process for process-by-process illustration of a method of manufacturing the field effect transistor Tr included in the inner circuit 3 and the Schottky barrier diode SBD included in the electro static discharge protection circuit 2.

First, the substrate 10 is prepared (see FIG. 6). For the substrate 10, a GaN substrate as the first compound semiconductor is used. The substrate 10 is formed, in a region where the field effect transistor Tr is to be formed, as the channel layer 31. In addition, the substrate 10 is formed, in a region where the Schottky barrier diode SBD is to be formed, as the cathode region 31C (the first compound semiconductor).

In the respective regions where the field effect transistor Tr and Schottky barrier diode SBD are to be formed, the recesses 10R are formed in the main surface portion of the substrate 10 (see FIG. 6). Each recess 10R is formed using a photolithography technique and an etching technique, for example.

In the recess 10R, GaN as the second compound semiconductor is formed (see FIG. 6). The GaN has an impurity density higher than that of the substrate 10. The GaN is formed using an epitaxial growth method.

The GaN is formed, in the region where the field effect transistor Tr is to be formed, as the main electrodes 34. In addition, the GaN is formed, in the region where the Schottky barrier diode SBD is to be formed, as the extraction electrode 34C (the second compound semiconductor). In other words, the main electrodes 34 and the extraction electrode 34C are formed in the same manufacturing process.

As illustrated in FIG. 6, except the regions of the main electrodes 34 and the extraction electrode 34C, the barrier layer 33 is formed on the main surface of the substrate 10. In the region where the field effect transistor Tr is to be formed, once the barrier layer 33 is formed, the two-dimensional electron gas 32 is generated in the vicinity of a surface of the channel layer 31.

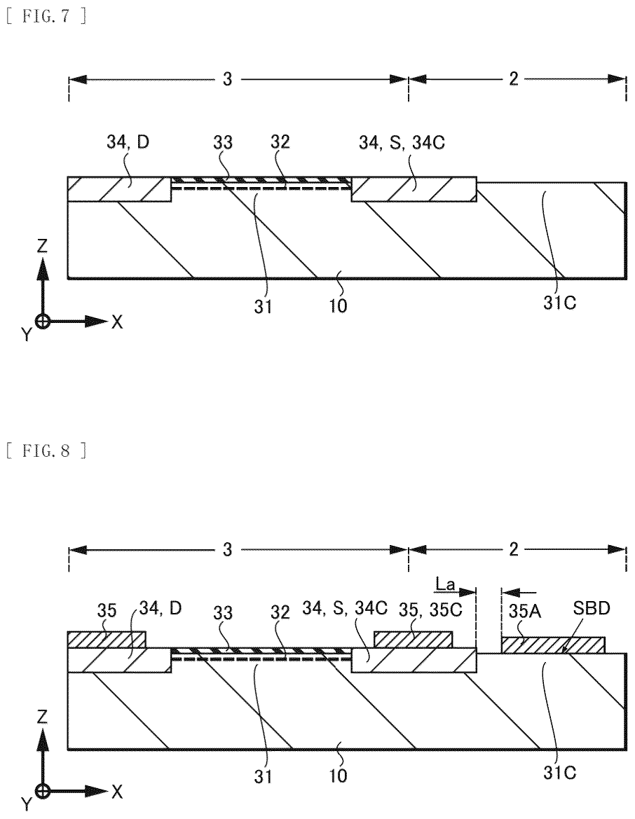

As illustrated in FIG. 7, in the region where the Schottky barrier diode SBD is to be formed, the barrier layer 33 is selectively removed.

As illustrated in FIG. 8, in the region where the field effect transistor Tr is to be formed, the electrode 35 (the third electrode) is formed on each main electrode 34. At the same process of the forming of the electrode 35, the anode electrode 35A (the first electrode) is formed on the cathode region 31C, and further the cathode electrode 35C (the second electrode) is formed on the extraction electrode 34C. In other words, the electrode 35, the anode electrode 35A, and the cathode electrode 35C are formed in the same manufacturing process.

The anode electrode 35A and the cathode electrode 35C are formed and thereby the Schottky barrier diode SBD is completed.

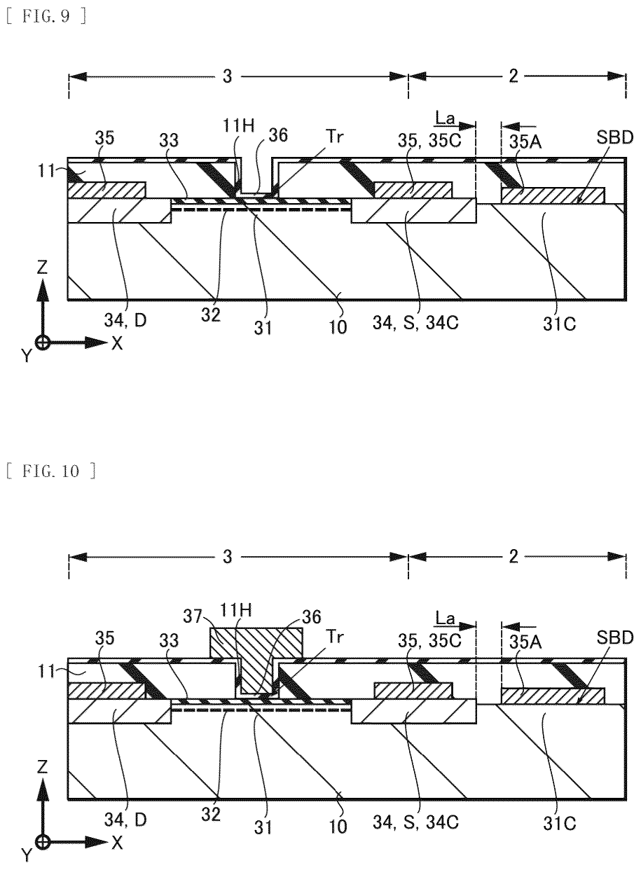

Subsequently, the interlayer insulator 11 is formed all over the surface of the substrate 10, the interlayer insulator 11 covering the electrode 35, the anode electrode 35A, and the cathode electrode 35C (see FIG. 9).

Next, in the region where the field effect transistor Tr is to be formed, the opening 11H is formed in the interlayer insulator 11 (see FIG. 9).

As illustrated in FIG. 9, in the region where the field effect transistor Tr is to be formed, the gate insulating layer 36 is formed on the barrier layer 33 through the opening 11H.

As illustrated in FIG. 10, in the region where the field effect transistor Tr is to be formed, the gate electrode 37 is formed on the gate insulating layer 36. The gate electrode 37 is formed and thereby the field effect transistor Tr is completed.

Thereafter, a wiring (the reference numeral of which is omitted), indicated simply by a solid line, is connected, and thereby the inner circuit 3 and the electro static discharge protection circuit 2 illustrated in FIGS. 1 to 3 described above are completed. When such a series of manufacturing processes above ends, the semiconductor device 1 according to the first embodiment is completed and the method of manufacturing the semiconductor device 1 ends.

### Workings and Effects

The semiconductor device 1 according to the first embodiment includes, as illustrated in FIGS. 2 and 3, the first compound semiconductor, the first electrode, the second compound semiconductor, and the second electrode.

The first compound semiconductor corresponds to the cathode region 31C.

The first electrode corresponds to the anode electrode 35A. The anode electrode 35A is disposed on the cathode region 31C and is coupled to the cathode region 31C by Schottky junction.

The second compound semiconductor corresponds to the extraction electrode 34C. The extraction electrode 34C is disposed on the cathode region 31C (the substrate 10) at a distance from the anode electrode 35A. The extraction electrode 34C has an impurity density higher than that of the cathode region 31C.

The second electrode corresponds to the cathode electrode 35C. The cathode electrode 35C is disposed on the extraction electrode 34C. The cathode electrode 35C includes an electrically conductive material same as that of the anode electrode 35A. The cathode electrode 35C is coupled to the extraction electrode 34C by ohmic junction. In other words, the cathode electrode 35C includes an electrically conductive layer same as that of the anode electrode 35A.

Here, the anode electrode 35A, the cathode region 31C, the extraction electrode 34C, and the cathode electrode 35C are included in the Schottky barrier diode SBD including electrodes as semiconductor elements. Thus, the anode electrode 35A and the cathode electrode 35C each include the same electrically conductive material, and this allows the semiconductor device 1 to be provided including the Schottky barrier diode SBD having a simple structure that includes a compound semiconductor and that is formed of a single type of electrode material.

In addition, in the semiconductor device 1, as illustrated in FIGS. 2 and 3, the first compound semiconductor of the cathode region 31C in the Schottky barrier diode SBD is GaN. Specifically, the first compound semiconductor is i-GaN. More specifically, the first compound semiconductor has an impurity density of 1×10¹⁷ [atoms/cm³] or less.

Meanwhile, in the semiconductor device 1, the second compound semiconductor of the extraction electrode 34C in the Schottky barrier diode SBD is GaN. Specifically, the second compound semiconductor has an n-type impurity density of 1×10¹⁹ [atoms/cm³] or more.

This allows the semiconductor device 1 to be provided including the Schottky barrier diode SBD having a simple structure that includes a compound semiconductor and that is formed of a single type of electrode material.

In addition, as illustrated in FIGS. 2 and 3, in the semiconductor device 1, the substrate 10 has, in a region at a distance from an anode electrode 31A, the recess 10R formed by digging down from the surface of the substrate 10 in the width direction. The extraction electrode 34C (the second compound semiconductor) is disposed in the recess 10R.

Thus, the surface of the cathode region 31C is at a height substantially equal to a height of the surface of the extraction electrode 34C, and this forms a flat region. The anode electrode 31A is formed on the cathode region 31C in such a flat region, and the cathode electrode 35C is formed on the extraction electrode 34C. This makes it possible for the anode electrode 31A and the cathode region 31C to include the same electrically conductive material, allowing the semiconductor device 1 to be provided including the Schottky barrier diode SBD that is formed of a single type of electrode material.

In addition, in the semiconductor device 1, as illustrated in FIGS. 2 and 3, the extraction electrode 34C (the second compound semiconductor) in the Schottky barrier diode SBD is provided, along the surface of the substrate 10, at a distance in a range longer than 0 and 0.9 [μm] or shorter from the anode electrode 35A.

As illustrated in FIGS. 4 and 5, adjusting the clearance La allows the operation voltage and operation current of the Schottky barrier diode SBD to be controlled as appropriate.

In addition, in the semiconductor device 1, as illustrated in FIG. 1, the Schottky barrier diode SBD is included in the electro static discharge protection circuit 2. This allows the semiconductor device 1 to be provided that makes it possible to enhance the electro static discharge protection performance.

In addition, as illustrated in FIG. 1, the semiconductor device 1 includes the field effect transistor Tr included in the inner circuit 3. The field effect transistor Tr includes, here, a high electron mobility transistor (HEMT). The field effect transistor Tr includes the channel layer 31, the barrier layer 33, the gate insulating layer 36, the gate electrode 37, and the pair of main electrodes 34.

The channel layer 31 includes the first compound semiconductor. The barrier layer 33 is disposed on the channel layer 31. The gate insulating layer 36 is disposed on the barrier layer 33 on the side opposite to the channel layer 31. The gate electrode 37 is disposed on the gate insulating layer 36 on the side opposite to the barrier layer 33. The pair of main electrodes 34 is disposed, at respective ones of both ends in the gate length direction of the gate electrode 37, on the substrate 10.

The cathode region 31C of the Schottky barrier diode SBD and the channel layer 31 of the field effect transistor Tr each include the same electrically conductive layer and each include the same electrically conductive material. In addition, the extraction electrode 35 of the Schottky barrier diode SBD and the main electrode 35 of the field effect transistor Tr each include the same electrically conductive layer and each include the same electrically conductive material. Moreover, the main electrode 35 of the field effect transistor Tr and the anode electrode 35A and cathode electrode 35C of the Schottky barrier diode SBD each include the same electrically conductive layer and each include the same electrically conductive material. Here, the main electrode 35, the anode electrode 35A, and the cathode electrode 35C each include, for example, Ti, Mo, Al, Ni, and Au successively stacked.

Thus, the components of the Schottky barrier diode SBD are configured using the components of the field effect transistor Tr, allowing the semiconductor device 1 having a simple structure to be provided.

Moreover, the method of manufacturing the semiconductor device 1 includes at least processes below. As illustrated in FIG. 6, a process of forming, on a portion of the cathode region 31C (the substrate 10), the extraction electrode 34C having an impurity density higher than that of the cathode region 31C. As illustrated in FIG. 8, a process of forming the anode electrode 35A on the cathode region 31C at a distance from the extraction electrode 34C, the anode electrode 35A forming Schottky junction. As illustrated in FIG. 8, a process of forming, at the same process as the anode electrode 35A. the cathode electrode 35C on the extraction electrode 34C, the cathode electrode 35C forming ohmic junction.

This makes it possible to provide the method of manufacturing the semiconductor device 1 including the Schottky barrier diode SBD that is formed of a single type of electrode material.

### 2. Second Embodiment

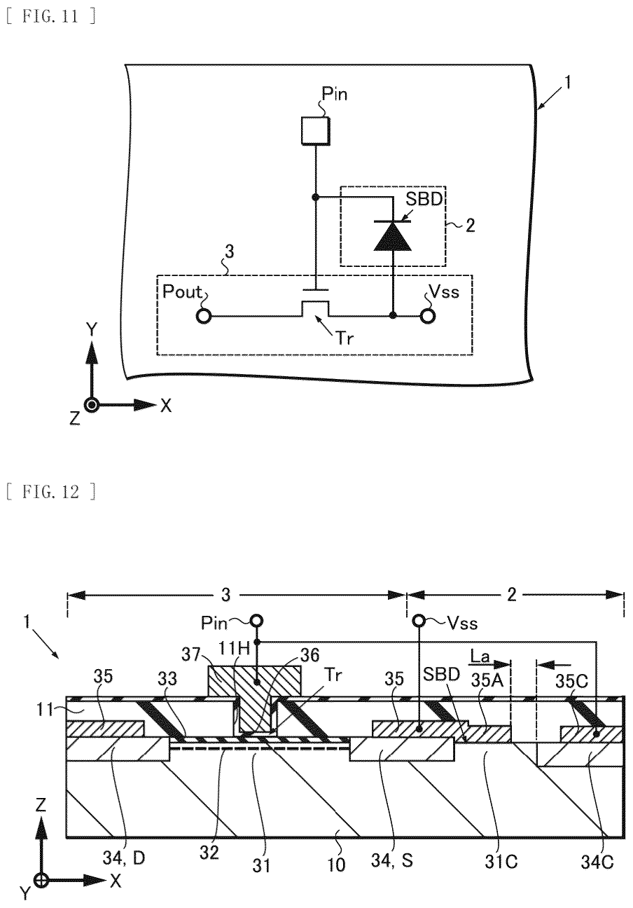

The semiconductor device 1, the electro static discharge protection circuit 2, and the inner circuit 3 according to the second embodiment of the present disclosure will be described with reference to FIGS. 11 and 12.

Note that, in the second embodiment and the embodiments to be described thereafter, a component the same or substantially the same as a component in the first embodiment is denoted with the same reference numeral and duplicate description is omitted.

### Configuration of Semiconductor Device 1

### (1) Circuit Configurations of Electro Static Discharge Protection Circuit 2 and Inner Circuit 3

FIG. 11 illustrates an example of a circuit configuration including the electro static discharge protection circuit 2 and the inner circuit 3 that are mounted in the semiconductor device 1 according to the second embodiment.

As compared with the semiconductor device 1 according to the first embodiment illustrated in FIG. 1 described above, as illustrated in FIG. 11, the Schottky barrier diode SBD of the electro static discharge protection circuit 2 in the semiconductor device 1 is inverse in the insertion direction. In other words, a cathode region of the Schottky barrier diode SBD is electrically connected in parallel between the input terminal Pin and the gate electrode of the field effect transistor Tr. Meanwhile, an anode region of the Schottky barrier diode SBD is electrically connected in parallel between the one of the main electrodes of the field effect transistor Tr and the power source terminal Vss.

### (2) Specific Device Configuration of Schottky Barrier Diode SBD

FIG. 12 illustrates an example of a longitudinal cross-sectional configuration of the field effect transistor Tr included in the inner circuit 3 and the Schottky barrier diode SBD included in the electro static discharge protection circuit 2.

As illustrated in FIG. 12, in the Schottky barrier diode SBD in the electro static discharge protection circuit 2, the anode electrode 31A is formed integrally with the electrode 35 of the field effect transistor Tr. The electrode 35 is disposed on the one of the main electrodes 34 used as the source region (S).

In other words, the electrode 35 disposed on the one of the main electrodes 34 of the field effect transistor Tr is provided extended to the cathode region 31C, and the electrode 35 extended is formed as the cathode electrode 35C.

Components other than the component described above are the same or substantially the same as the components of the semiconductor device 1 according to the first embodiment described above.

### Workings and Effects

The semiconductor device 1 according to the second embodiment makes it possible to obtain workings and effects similar to the workings and effects possible to be obtained in the semiconductor device 1 according to the first embodiment.

### 3. Third Embodiment

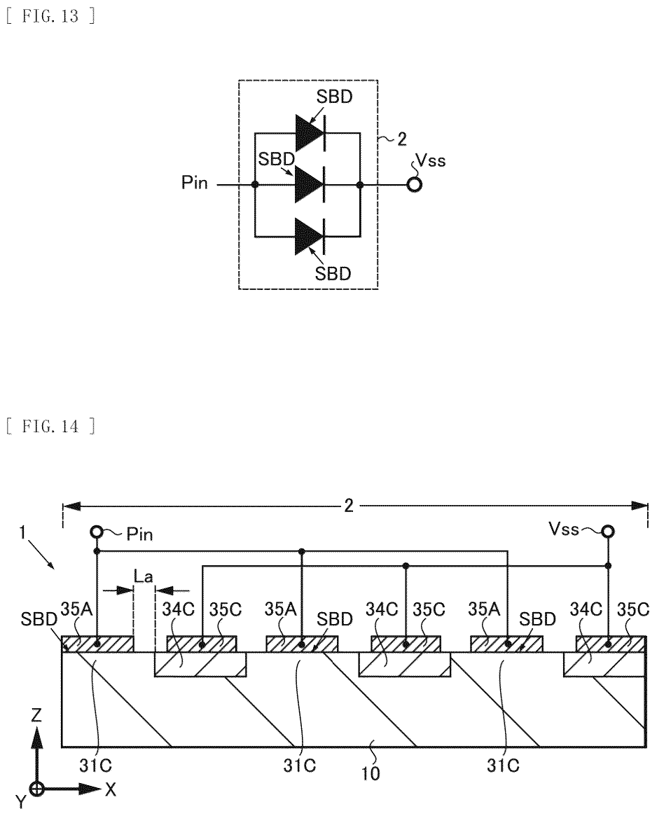

The semiconductor device 1, the electro static discharge protection circuit 2, and the inner circuit 3 according to the third embodiment of the present disclosure will be described with reference to FIGS. 13 and 14.

### Configuration of Semiconductor Device 1

### (1) Circuit Configuration of Electro Static Discharge Protection Circuit 2

FIG. 13 illustrates an example of a circuit configuration including the electro static discharge protection circuit 2 mounted in the semiconductor device 1 according to the third embodiment.

As illustrated in FIG. 13, the electro static discharge protection circuit 2 mounted in the semiconductor device 1 includes a plurality of Schottky barrier diodes SBD. Here, three Schottky barrier diodes SBD electrically connected in parallel are included in the electro static discharge protection circuit 2.

### (2) Specific Device Configuration of Schottky Barrier Diode SBD

FIG. 14 illustrates an example of a longitudinal cross-sectional configuration of the Schottky barrier diodes SBD included in the electro static discharge protection circuit 2. As illustrated in FIG. 14, the electro static discharge protection circuit 2 includes three Schottky barrier diodes SBD that are electrically connected in parallel.

Components other than the components described above are the same or substantially the same as the components of the semiconductor device 1 according to the first embodiment or second embodiment described above.

Note that the number of Schottky barrier diodes SBD connected may be two or four or more.

### Workings and Effects

The semiconductor device 1 according to the third embodiment makes it possible to obtain workings and effects similar to the workings and effects possible to be obtained in the semiconductor device 1 according to the first embodiment or the semiconductor device 1 according to the second embodiment.

In addition, in the semiconductor device 1 according to the third embodiment, as illustrated in FIGS. 13 and 14, the plurality of Schottky barrier diodes SBD electrically connected in parallel is included in the electro static discharge protection circuit 2. The current characteristics of the Schottky barrier diodes SBD are optimally designed by trade-off between protection characteristics and a current leakage in operation of the device. The plurality of Schottky barrier diodes SBD disposed allows the current amount to be raised. In addition, in the electro static discharge protection circuit 2, the plurality of Schottky barrier diodes SBD makes it possible to adjust the aspect ratio of the entire protection element as desired. This allows, in the semiconductor device 1, the electro static discharge protection circuit 2 to save space.

### 4. Fourth Embodiment

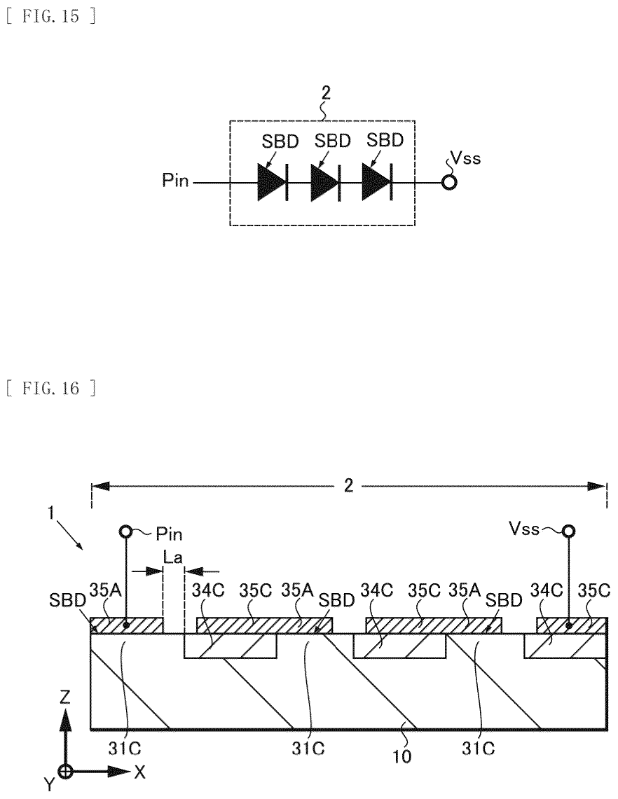

The semiconductor device 1, the electro static discharge protection circuit 2, and the inner circuit 3 according to the fourth embodiment of the present disclosure will be described with reference to FIGS. 15 and 16.

### Configuration of Semiconductor Device 1

### (1) Circuit Configuration of Electro Static Discharge Protection Circuit 2

FIG. 15 illustrates an example of a circuit configuration including the electro static discharge protection circuit 2 mounted in the semiconductor device 1 according to the fourth embodiment.

As illustrated in FIG. 15, the electro static discharge protection circuit 2 mounted in the semiconductor device 1 includes a plurality of Schottky barrier diodes SBD. Here, three Schottky barrier diodes SBD electrically connected in series are included in the electro static discharge protection circuit 2.

(2) Specific Device Configuration of Schottky Barrier Diode SBD FIG. 16 illustrates an example of a longitudinal cross-sectional configuration of the Schottky barrier diodes SBD included in the electro static discharge protection circuit 2.

As illustrated in FIG. 16, the electro static discharge protection circuit 2 includes three Schottky barrier diodes SBD that are electrically connected in series.

In the fourth embodiment, the cathode electrode 35C of any one of the Schottky barrier diodes SBD is provided extended to the cathode region 31C of the next-stage Schottky barrier diode SBD, and is used, in the extended region, as the anode electrode 35A.

Components other than the components described above are the same or substantially the same as the components of the semiconductor device 1 according to the first embodiment or second embodiment described above.

Note that the number of Schottky barrier diodes SBD connected may be two or four or more.

### Workings and Effects

The semiconductor device 1 according to the fourth embodiment makes it possible to obtain workings and effects similar to the workings and effects possible to be obtained in the semiconductor device 1 according to the first embodiment or the semiconductor device 1 according to the second embodiment.

In addition, in the semiconductor device 1 according to the fourth embodiment, as illustrated in FIGS. 15 and 16, the plurality of single Schottky barrier diodes SBD each having any clearance dimension La is connected in series, allowing the operation voltage of the entire set of Schottky barrier diodes SBD to be controlled. In other words, adjustment of the number of stages allows the operation voltage of the entire set of Schottky barrier diodes SBD to be easily controlled.

In addition, in the semiconductor device 1, as illustrated in FIG. 16, the cathode electrode 35C of any one of the Schottky barrier diodes SBD is configured integrally with the anode electrode 35A of the next-stage Schottky barrier diode SBD.

With this, no separate region is provided between the cathode electrode 35C and the anode electrode 35A, allowing the area occupied by the electro static discharge protection circuit 2 to be reduced.

### 5. Fifth Embodiment

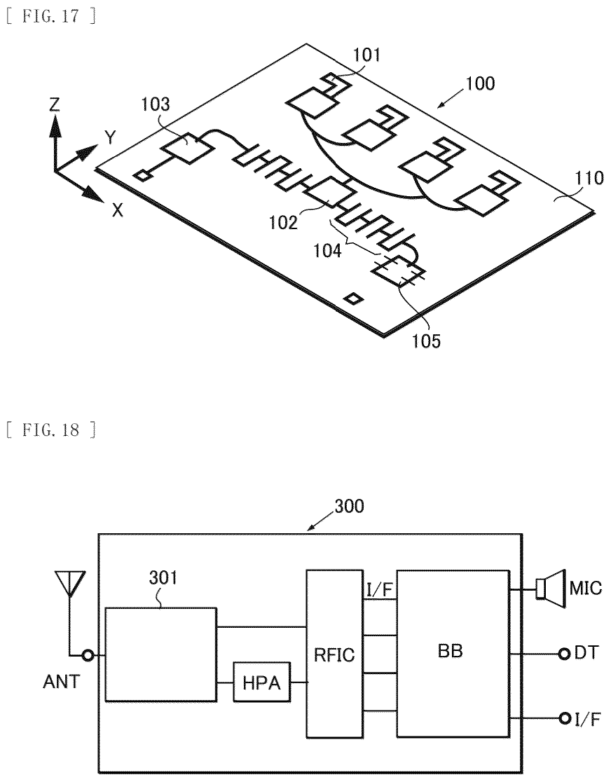

A semiconductor module 100 according to the fifth embodiment of the present disclosure will be described with reference to FIG. 17. FIG. 17 illustrates a schematic structure of the semiconductor module 100 according to the fifth embodiment.

### Configuration of Semiconductor Module 100

The semiconductor module 100 according to the fifth embodiment is, for example, an antenna integrated module including, as one module, an edge antenna 101 disposed in an array and front-end parts that are implemented on a substrate 110. The front-end parts include, for example, a switch 102, a low-noise amplifier 103, a bandpass filter 104, and a power amplifier 105. The semiconductor module 100 is possible to be used as a transceiver for communication, for example.

The semiconductor module 100 includes, as a transistor included in, for example, the switch 102, low-noise amplifier 103, or power amplifier 105, the semiconductor device 1 according to any one of the first to fourth embodiments.

### Workings and Effects

The semiconductor module 100 according to the fifth embodiment, with the semiconductor device 1 included, makes it possible to achieve higher speed, higher efficiency, and lower power consumption in wireless communication.

In addition, the electro static discharge protection circuit 2 according to any one of the first to fourth embodiments is mounted in the semiconductor device 1. With this, in the semiconductor module 100, it is possible to achieve that the area occupied by the electro static discharge protection circuit 2 is reduced, with the structure of the electro static discharge protection circuit 2 being simplified and electro static breakdown protection resistance being enhanced.

### 6. Sixth Embodiment

A wireless communication device 300 according to the sixth embodiment of the present disclosure will be described with reference to FIG. 18. FIG. 18 schematically illustrates a block configuration of the wireless communication device 300 according to the sixth embodiment.

### Configuration of Wireless Communication Device 300

The wireless communication device 300 according to the sixth embodiment includes an antenna ANT, an antenna switch circuit 301, a high power amplifier HPA, a high-frequency integrated circuit (Radio Frequency Integrated Circuit) RFIC, a baseband section BB, a voice output section MIC, a data output section DT, and an interface I/F. The interface I/F includes, for example, a wireless local area network (W-LAN) and Bluetooth (registered trademark). The wireless communication device 300 is, for example, a mobile phone system with multifunction such as voice, data communication, or LAN connection.

The wireless communication device 300 includes, as a transistor included in, for example, the antenna switch circuit 301, high power amplifier HPA, high-frequency integrated circuit RFIC, or baseband section BB, the semiconductor device 1 according to any one of the first to fourth embodiments.

### Workings and Effects

The wireless communication device 300 according to the sixth embodiment, with the semiconductor device 1 included, makes it possible to achieve higher speed, higher efficiency, and lower power consumption in wireless communication. With this, in a case where the wireless communication device 300 is a mobile communication terminal, the wireless communication device 300 makes it possible to further extend the usage time, allowing the portability to be further enhanced.

In addition, the electro static discharge protection circuit 2 according to any one of the first to fourth embodiments is mounted in the semiconductor device 1. With this, in the wireless communication device 300, it is possible to achieve that the area occupied by the electro static discharge protection circuit 2 is reduced, with the structure of the electro static discharge protection circuit 2 being simplified and electro static breakdown protection resistance being enhanced.

### 7. Other Embodiments

The present technique is not limited to the embodiments described above, and is modifiable, within a range not departing from the gist, in a variety of ways.

For example, in a semiconductor device according to the present technique, a compound semiconductor is possible to be used that allows similar workings and effects to be provided and that is other than GaN.

In addition, in the present technique, the main electrode of the field effect transistor and the extraction electrode of the Schottky barrier diode may be stacked on a compound semiconductor, not in the recess.

As described above, a semiconductor device according to the first embodiment includes a first compound semiconductor, a first electrode, a second compound semiconductor, and a second electrode.

The first electrode is disposed on the first compound semiconductor and is coupled to the first compound semiconductor by Schottky junction. The second compound semiconductor is disposed on the first compound semiconductor at a distance from the first electrode. The second compound semiconductor has an impurity density higher than that of the first compound semiconductor. The second electrode is disposed on the second compound semiconductor. The second electrode includes an electrically conductive material same as that of the first electrode and is coupled to the second compound semiconductor by ohmic junction.

Thus, the first electrode and the second electrode each include the same electrically conductive material, and this allows the semiconductor device to be provided including the Schottky barrier diode having a simple structure that includes a compound semiconductor and that is formed of a single type of electrode material.

In a method of manufacturing a semiconductor device according to the second embodiment of the present disclosure, first, on a portion of a first compound semiconductor, a second compound semiconductor having a higher impurity density than the first compound semiconductor is formed. Next, a first electrode is formed on the first compound semiconductor at a distance from the second compound semiconductor, the first electrode forming Schottky junction. Here, at the same process of the forming of the first electrode, a second electrode is formed on the second compound semiconductor, the second electrode forming ohmic junction.

Thus, the first electrode and the second electrode are each formed at the same process, allowing the number of manufacturing processes for the semiconductor device to be reduced.

A semiconductor module according to the third embodiment of the present disclosure includes a semiconductor device. The semiconductor device is the semiconductor device according to the first embodiment.

With this, the semiconductor module makes it possible to obtain workings and effects similar to the workings and effects possible to be obtained in the semiconductor device according to the first embodiment.

Electronic apparatus according to the fourth embodiment of the present disclosure includes a semiconductor device. The semiconductor device is the semiconductor device according to the first embodiment.

With this, the electronic apparatus makes it possible to obtain workings and effects similar to the workings and effects possible to be obtained in the semiconductor device according to the first embodiment.

### Configuration of Present Technique

The present technique includes the following configuration. The present technique with the following configuration makes it possible, in the semiconductor device, the method of manufacturing the semiconductor device, the semiconductor module, and the electronic apparatus, to provide a Schottky barrier diode having a simple structure that includes a compound semiconductor and that is formed of a single type of electrode material.

(1)

A semiconductor device including:
a first compound semiconductor;
a first electrode disposed on the first compound semiconductor, the first electrode being coupled to the first compound semiconductor by Schottky junction;
a second compound semiconductor disposed on the first compound semiconductor at a distance from the first electrode, the second compound semiconductor having a higher impurity density than the first compound semiconductor; and
a second electrode disposed on the second compound semiconductor, the second electrode including the same electrically conductive material as the first electrode and being coupled to the second compound semiconductor by ohmic junction.
   (2)

The semiconductor device according to (1), in which the first compound semiconductor includes GaN.

(3)

The semiconductor device according to (1) or (2), in which the first compound semiconductor includes i-GaN.

(4)

The semiconductor device according to any one of (1) to (3), in which the first compound semiconductor has an impurity density of 1×10¹⁷ [atoms/cm³] or less.

(5)

The semiconductor device according to any one of (1) to (4), in which the second compound semiconductor includes GaN.

(6) The semiconductor device according to any one of (1) to (5), in which the second compound semiconductor has an n-type impurity density of 1×10¹⁹ [atoms/cm³] or more.
(7)

The semiconductor device according to any one of (1) to (6), further including, in a region of the first compound semiconductor at a distance from the first electrode, a recess that is dug down from a surface of the first compound semiconductor in a width direction, and

the second compound semiconductor is disposed in the recess.

(8)

The semiconductor device according to any one of (1) to (7), in which the first electrode and the second electrode are each provided in the same electrically conductive layer.

(9)

The semiconductor device according to any one of (1) to (8), in which a Schottky barrier diode is provided at a junction of the first electrode and the first compound semiconductor.

(10)

The semiconductor device according to any one of (1) to (9), in which
the first electrode comprises an anode electrode, and
the second electrode comprises a cathode electrode.
   (11)

The semiconductor device according to any one of (1) to (10), in which the second compound semiconductor is provided, along a surface of the first compound semiconductor, at a distance in a range longer than 0 and 0.9 [μm] or shorter from the first electrode.

(12)

The semiconductor device according to (9) or (10), in which
a plurality of the Schottky barrier diodes is disposed, and
the plurality of the Schottky barrier diodes is electrically coupled to each other in parallel.
   (13)

The semiconductor device according to (9) or (10), in which
a plurality of the Schottky barrier diodes is disposed, and
the plurality of the Schottky barrier diodes is electrically coupled to each other in series.
   (14)

The semiconductor device according to any one of (9) to (13), in which the Schottky barrier diode(s) is included in an electro static discharge protection circuit.

(15)

The semiconductor device according to any one of (1) to (14), further including:
a channel layer including the first compound semiconductor;
a barrier layer disposed on the channel layer;
a gate insulating layer disposed on the barrier layer on a side opposite to the channel layer;
a gate electrode disposed on the gate insulating layer on a side opposite to the barrier layer; and
a high electron mobility transistor including, at both ends in a gate length direction of the gate electrode, a pair of main electrodes disposed on the first compound semiconductor.
   (16)

The semiconductor device according to (15), in which
the first compound semiconductor and the channel layer each include the same electrically conductive layer and each include the same electrically conductive material,
the second compound semiconductor and the main electrodes each include the same electrically conductive layer and each include the same electrically conductive material, and
a third electrode coupled to any one of the main electrodes, the first electrode, and the second electrode each include the same electrically conductive layer and each include the same electrically conductive material.
   (17)

The semiconductor device according to (16), in which the first electrode, the second electrode, and the third electrode each include Ti, Mo, Al, Ni, and Au successively stacked.

(18)

A method of manufacturing a semiconductor device, the method including:
forming. on a portion of a first compound semiconductor, a second compound semiconductor having a higher impurity density than the first compound semiconductor;
forming a first electrode on the first compound semiconductor at a distance from the second compound semiconductor, the first electrode forming Schottky junction; and
forming, in a same process as the forming the first electrode, a second electrode on the second compound semiconductor, the second electrode forming ohmic junction.
   (19)

A semiconductor module including:
a semiconductor device, in which
the semiconductor device includes
   a first compound semiconductor,
   a first electrode disposed on the first compound semiconductor, the first electrode being coupled to the first compound semiconductor by Schottky junction,
   a second compound semiconductor disposed on the first compound semiconductor at a distance from the first electrode, the second compound semiconductor having a higher impurity density than the first compound semiconductor, and a second electrode disposed on the second compound semiconductor, the second electrode including the same electrically conductive material as the first electrode and being coupled to the second compound semiconductor by ohmic junction.
      (20)

An electronic apparatus including:
a semiconductor device, in which
the semiconductor device includes
   a first compound semiconductor,
   a first electrode disposed on the first compound semiconductor, the first electrode being coupled to the first compound semiconductor by Schottky junction,
   a second compound semiconductor disposed on the first compound semiconductor at a distance from the first electrode, the second compound semiconductor having a higher impurity density than the first compound semiconductor, and
   a second electrode disposed on the second compound semiconductor, the second electrode including the same electrically conductive material as the first electrode and being coupled to the second compound semiconductor by ohmic junction.

The present application claims the benefit of Japanese Priority Patent Application JP2022-149237 filed with the Japan Patent Office on Sep. 20, 2022, the entire contents of which are incorporated herein by reference.

It should be understood by those skilled in the art that various modifications, combinations, sub-combinations, and alterations may occur depending on design requirements and other factors insofar as they are within the scope of the appended claims or the equivalents thereof.

1. A semiconductor device comprising:
a first compound semiconductor;
a first electrode disposed on the first compound semiconductor, the first electrode being coupled to the first compound semiconductor by Schottky junction;
a second compound semiconductor disposed on the first compound semiconductor at a distance from the first electrode, the second compound semiconductor having a higher impurity density than the first compound semiconductor; and
a second electrode disposed on the second compound semiconductor, the second electrode including a same electrically conductive material as the first electrode and being coupled to the second compound semiconductor by ohmic junction.

2. The semiconductor device according to claim 1, wherein
the first compound semiconductor comprises GaN.

3. The semiconductor device according to claim 1, wherein the first compound semiconductor comprises i-GaN.

4. The semiconductor device according to claim 1, wherein
the first compound semiconductor has an impurity density of 1×10¹⁷ [atoms/cm³] or less.

5. The semiconductor device according to claim 1, wherein
the second compound semiconductor comprises GaN.

6. The semiconductor device according to claim 1, wherein
the second compound semiconductor has an n-type impurity density of 11¹⁹ [atoms/cm³] or more.

7. The semiconductor device according to claim 1, further comprising, in a region of the first compound semiconductor at a distance from the first electrode, a recess that is dug down from a surface of the first compound semiconductor in a width direction, and
the second compound semiconductor is disposed in the recess.

8. The semiconductor device according to claim 1, wherein
the first electrode and the second electrode are each provided in a same electrically conductive layer.

9. The semiconductor device according to claim 1, wherein
a Schottky barrier diode is provided at a junction of the first electrode and the first compound semiconductor.

10. The semiconductor device according to claim 9, wherein
the first electrode comprises an anode electrode, and
the second electrode comprises a cathode electrode.

11. The semiconductor device according to claim 1, wherein
the second compound semiconductor is provided, along a surface of the first compound semiconductor, at a distance in a range longer than 0 and 0.9 [μm] or shorter from the first electrode.

12. The semiconductor device according to claim 9, wherein
a plurality of the Schottky barrier diodes is disposed, and
the plurality of the Schottky barrier diodes is electrically coupled to each other in parallel.

13. The semiconductor device according to claim 9, wherein
a plurality of the Schottky barrier diodes is disposed, and
the plurality of the Schottky barrier diodes is electrically coupled to each other in series.

14. The semiconductor device according to claim 9, wherein
the Schottky barrier diode is included in an electro static discharge protection circuit.

15. The semiconductor device according to claim 1, further comprising:
a channel layer including the first compound semiconductor;
a barrier layer disposed on the channel layer;
a gate insulating layer disposed on the barrier layer on a side opposite to the channel layer;
a gate electrode disposed on the gate insulating layer on a side opposite to the barrier layer; and
a high electron mobility transistor including, at both ends in a gate length direction of the gate electrode, a pair of main electrodes disposed on the first compound semiconductor.

16. The semiconductor device according to claim 15, wherein
the first compound semiconductor and the channel layer each include a same electrically conductive layer and each include a same electrically conductive material,
the second compound semiconductor and the main electrodes each include a same electrically conductive layer and each include a same electrically conductive material, and
a third electrode coupled to any one of the main electrodes, the first electrode, and the second electrode each include a same electrically conductive layer and each include a same electrically conductive material.

17. The semiconductor device according to claim 16, wherein
the first electrode, the second electrode, and the third electrode each include Ti, Mo, Al, Ni, and Au successively stacked.

18. A method of manufacturing a semiconductor device, the method comprising:
forming, on a portion of a first compound semiconductor, a second compound semiconductor having a higher impurity density than the first compound semiconductor;
forming a first electrode on the first compound semiconductor at a distance from the second compound semiconductor, the first electrode forming Schottky junction; and
forming, in a same process as the forming the first electrode, a second electrode on the second compound semiconductor, the second electrode forming ohmic junction.

19. A semiconductor module comprising:
a semiconductor device, wherein
the semiconductor device includes
a first compound semiconductor,
a first electrode disposed on the first compound semiconductor, the first electrode being coupled to the first compound semiconductor by Schottky junction,
a second compound semiconductor disposed on the first compound semiconductor at a distance from the first electrode, the second compound semiconductor having a higher impurity density than the first compound semiconductor, and
a second electrode disposed on the second compound semiconductor, the second electrode including a same electrically conductive material as the first electrode and being coupled to the second compound semiconductor by ohmic junction.

20. An electronic apparatus comprising:
a semiconductor device, wherein
the semiconductor device includes
a first compound semiconductor,
a first electrode disposed on the first compound semiconductor, the first electrode being coupled to the first compound semiconductor by Schottky junction,
a second compound semiconductor disposed on the first compound semiconductor at a distance from the first electrode, the second compound semiconductor having a higher impurity density than the first compound semiconductor, and
a second electrode disposed on the second compound semiconductor, the second electrode including a same electrically conductive material as the first electrode and being coupled to the second compound semiconductor by ohmic junction.
